(19) United States
(12) Patent Application Publication
(10) Pub. No.: US 2017/0295648 A1
(43) Pub. Date: Oct. 12, 2017

(54) ELECTRONIC DEVICE

(71) Applicant: KONICA MINOTA, INC., Tokyo (JP)

(72) Inventor: Seiji OHASHI, Kokubunji-shi, Tokyo (JP)

(21) Appl. No.: 15/517,109

(22) PCT Filed: Oct. 20, 2015
(86) PCT No.: PCT/JP2015/079579

§ 371 Date: Apr. 5, 2017

(30) Foreign Application Priority Data
Dec. 2, 2014 (JP) 2014-243810

(51) Int. Cl. H05K 1/14; G06F 1/16; H04M 1/02; H01L 51/52

(52) U.S. Cl. CPC H05K 1/148; H01L 51/524; H05K 1/144; G06F 1/1626; H04M 1/0266; G09F 9/30

(57) ABSTRACT

Provided is an electronic device that makes it possible to minimize decreases in mounting yield. In the electronic device, an OLED panel and an FPC are crimped and connected using an ACF. The FPC comprises a pattern that is symmetrical with respect to a line corresponding to a direction perpendicular to a straight line that connects electrodes connected to the OLED panel within the range in which the OLED panel is mounted.

### TECHNICAL FIELD

The present invention relates to an electronic device including an organic EL element panel connected to an FPC (flexible printed circuit) substrate.

### BACKGROUND ART

In recent years, LED (light emitting diode) using a light guide plate and OLED (organic light emitting diode) have been drawing attention as a planar light source body. The light guide plate LED has come to be used in various scenes and applications as backlight for LCD (liquid crystal display) and the like, in addition to general lighting.

Since around 2008, an amount of production of smart devices including smart phones and tablets has been increased, and the light guide plate LED has been used as a key member. The light guide plate LED is mainly used for backlight application of a main display (LCD), and another use application includes the light guide plate LED being often incorporated also as backlight of a common function key button located at a lower portion of a device. There are often used three types of common function key button including: home (displayed with a square mark or the like); return (displayed with an arrow mark or the like); and search (displayed with a mark of a magnifying glass or the like). Generally, a pattern including the mark desired to be displayed is printed on a cover glass, the light guide plate LED as described above is disposed at the lower portion of the cover glass, the LED emits light as necessary, the light is guided through the light guide plate (film), and the light is taken out to a display side through a diffusion member having a dot-like shape printed on a pattern portion (refer to Patent Literature 1, for example).

In addition, there is suggested, as a method for realizing the above described common function key button by the use of the OLED panel, a method for forming a light emitting pattern in which an organic light emitting layer is irradiated with UV light having a predetermined pattern, and thus the irradiation destroys the organic light emitting layer of an irradiation portion, to thereby cause only a pattern of a non-irradiation portion to emit light (refer to Patent Literature 2, for example). In comparison with the method in which the light guide plate and the LED are combined with each other, the light emitting pattern itself can be formed by application of the above described method, and thus a panel having low electricity consumption and high efficiency can be provided.

Furthermore, when a plurality of display patterns is provided on the OLED panel as in the case of the above described common function key button, electric power is generally supplied from an electric power source circuit to the OLED panel by the use of FPC (flexible printed circuit).

Here, a method for mounting the FPC and a glass substrate panel includes a method for crimping and connecting the FPC and the glass substrate panel with each other by the use of ACF (anisotropic conductive film) at an electrically contacting portion therebetween (refer to Patent Literature 3, for example). Moreover, there is a method for arranging a dummy pattern in the FPC in order to prevent cutting lines of the FPC caused by difference in wire expansion coefficients between the panel and the FPC (refer to Patent Literature 4, for example).

### CITATION LIST

### Patent Literature

PTL 1: Japanese Patent Laid-Open No. 2012-194291

PTL 2: Japanese Patent Laid-Open No. 2001-167881

PTL 3: Japanese Patent Laid-Open No. 2012-54564

PTL 4: Japanese Patent Laid-Open No. 2000-252602

### SUMMARY OF INVENTION

### Technical Problem

However, in the mounting method for crimping and connecting the FPC by the use of the ACF, when the OLED panel is applied to the common function key of the smart device, a crimping pressure is concentrated on one portion depending on wiring layout on the FPC, and thus mounting yield is decreased.

In order to solve the problem described above, the present invention provides an electronic device capable of minimizing decrease in mounting yield.

### Solution to Problem

In an electronic device of the present invention in which an OLED (organic light emitting diode) panel and an FPC (flexible printed circuit) are crimped and connected to each other using an ACF (anisotropic conductive film), the FPC has a pattern that is symmetrical with respect to a line corresponding to a direction perpendicular to a straight line that connects electrodes connected to the OLED panel with each other within a range in which the OLED panel is mounted.

### Advantageous Effects of Invention

According to the present invention, the electronic device capable of minimizing the decrease in the mounting yield can be provided.

### BRIEF DESCRIPTION OF DRAWINGS

FIG. 1 is a plan view of a smart device.

FIG. 2 is a cross-sectional view along the line A-A of the smart device shown in FIG. 1.

FIG. 3 is an arrangement plan view of an icon display portion of the smart device.

FIG. 4 is a diagram showing a layout of a portion of FPC to which an OLED panel is to be connected.

FIG. 5 is a diagram showing a method for joining the OLED panel and the FPC to each other.

FIG. 6 is a diagram showing a method for joining the OLED panel and the FPC to each other.

FIG. 7 is an arrangement plan view of the OLED panel and the FPC at an icon display portion of an electronic device of a first embodiment.

FIG. 8 is a diagram showing a layout of a portion of the FPC to which the OLED panel of the electronic device is to be connected according to the first embodiment.

FIG. 9 is a diagram showing the FPC and the OLED panel before being joined to each other on a cross-section along the line A-A at the icon display portion shown in FIG. 7.

FIG. 10 is a diagram showing the FPC and the OLED panel in a crimped state on the cross-section along the line A-A at the icon display portion shown in FIG. 7.

FIG. 11 is an arrangement plan view of the OLED panel and the FPC at the icon display portion of the electronic device of a second embodiment.

FIG. 12 is a diagram showing a layout of a portion of the FPC to which the OLED panel of the electronic device of the second embodiment is to be connected.

FIG. 13 is a cross-sectional view along the line A-A of the icon display portion shown in FIG. 11.

### DESCRIPTION OF EMBODIMENTS

Hereinafter, examples of the embodiments for carrying out the present invention will be described, but the present invention is not limited to the following examples.

Note that the description will be performed in a following order.
1. Summary of electronic device
2. First embodiment of electronic device
3. Second embodiment of electronic device

### 1. Summary of Electronic Device

Summary of the electronic device will be described prior to describing embodiments of electronic devices.

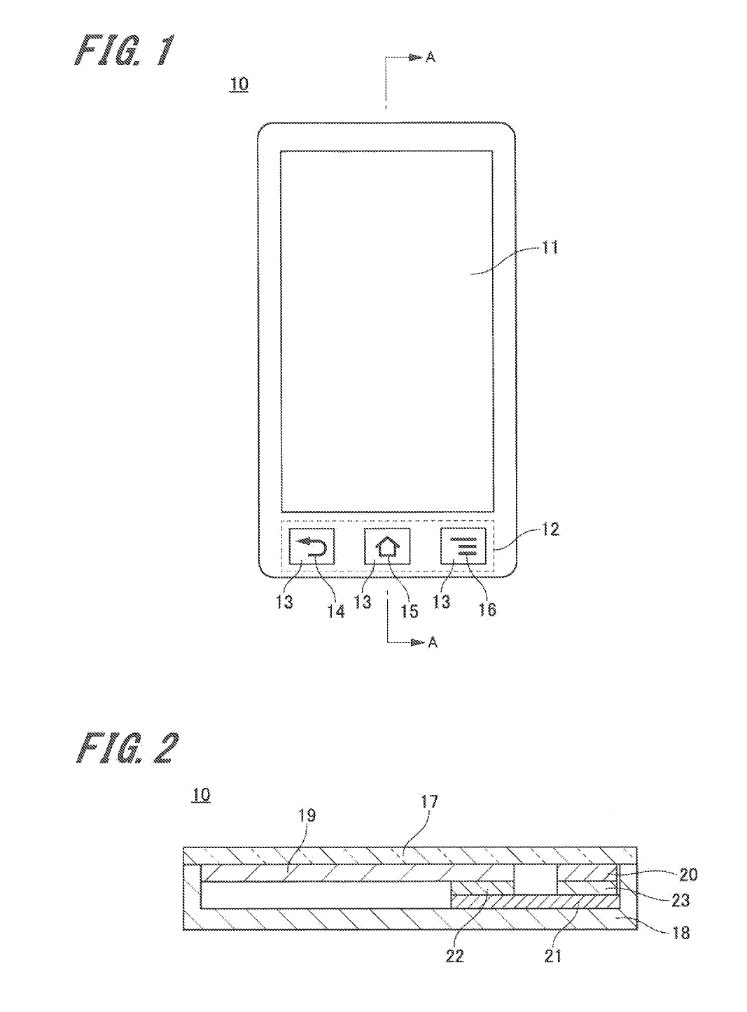

FIG. 1 is a plan view of a smart device as one example of a general electronic device. Further, FIG. 2 shows a cross-sectional view along the line A-A of the smart device shown in FIG. 1. A smart device 10 shown in FIGS. 1 and 2 are, for example, a smart phone and a tablet-type computer. Note that FIGS. 1 and 2 only show main configurations used for describing the present embodiment, and other configurations of an electric power source portion and the like are not described.

As shown in FIG. 1, the smart device 10 is provided with a plurality of common function keys 13 at an icon display portion 12 located at a lower portion of a main display screen 11. Furthermore, the common function keys 13 are displayed with icons 14, 15, and 16. Switches (not shown) are mounted at the lower portion of the common function keys 13 displayed with the icons 14, 15, and 16. The switches located at the lower portion are turned on by contact with the icons 14, 15, and 16 to thereby allow switching of functions of the smart device 10.

Furthermore, as shown in FIG. 2, the smart device 10 includes: a casing 18 constituting a bottom surface and side surfaces of the smart device 10; respective elements arranged inside the casing 18; and a cover glass 17 that covers an upper portion inside the casing 18 where the elements are formed and that is provided on an entire surface on a front surface side of the smart device 10.

The casing 18 is provided with a main display panel 19 including a liquid crystal panel and the like for constituting the main display screen 11, an OLED panel 20 for constituting the icon display portion 12, a PCB (printed circuit board) 21 forming each circuit of the smart device 10, and FPCs (flexible printed circuits) 22 and 23 connecting the main display panel 19 and the OLED panel 20 with the PCB 21.

The main display panel 19, the OLED panel 20, the PCB 21, and the FPCs 22 and 23 are crimped and connected to one another via an ACF (Anisotropic Conductive Film) and the like (not shown).

As shown in FIG. 2, the main display panel 19 and the OLED panel 20 are connected to the PCB 21 via the FPCs 22 and 23, and then connected to each of various control portions and circuits provided on the PCB 21. Furthermore, an electric power is typically supplied from the electric power source circuit provided on the PCB 21.

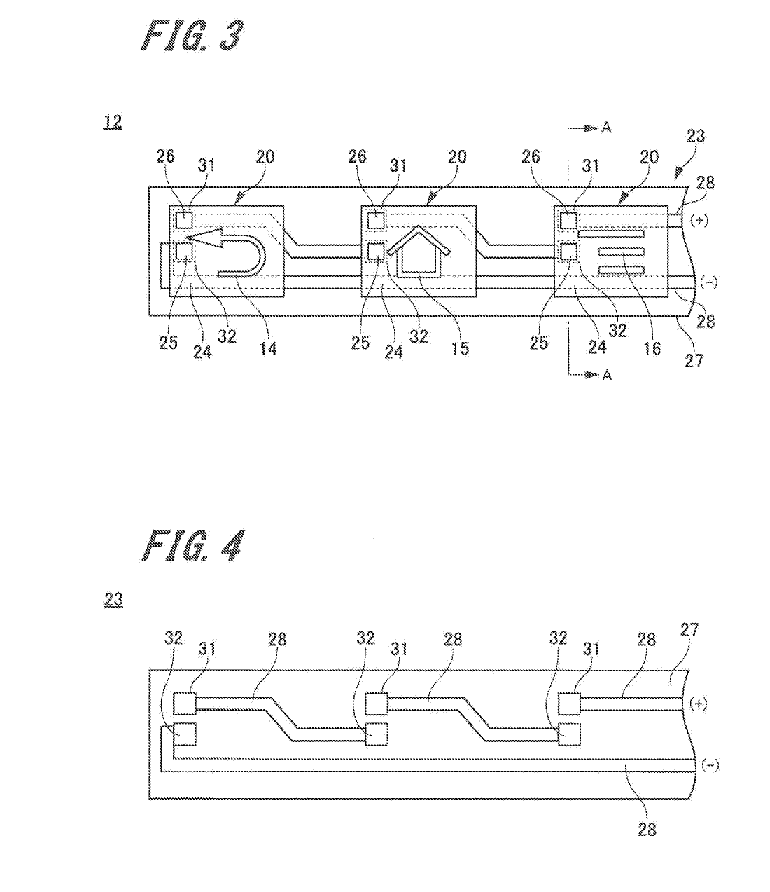

Next, FIG. 3 is an arrangement plan view of the icon display portion 12. As shown in FIG. 3, in this example, the icon display portion 12 includes three common function keys. Three icons 14, 15, and 16 are provided corresponding to the three common function keys. The icons 14, 15, and 16 are each formed with an individual OLED panel 20.

The OLED panel 20 is provided with a cathode electrode (negative pole) and an anode electrode (positive pole) on a substrate 24, and a light emitting layer sandwiched by these electrodes. In the OLED panel 20, the light emitting layer sandwiched by the cathode electrode and the anode electrode is formed in a predetermined pattern, and thus the icons 14, 15, and 16 are formed such that they can be displayed on the common function keys.

Furthermore, there are provided, on the substrate 24, a cathode takeout electrode 25 and an anode takeout electrode 26 which are connected to the cathode electrode and the anode electrode described above to thereby connect to the outside from the OLED panel 20. The cathode takeout electrode 25 and the anode takeout electrode 26 are each connected to the PCB 21 and FPC 23 shown in FIG. 2 described above, via ACF (anisotropic conductive film) and the like (not shown).

Furthermore, FIG. 4 shows a layout of a portion to be connected to the OLED panel 20, being an essential part of the FPC 23. The FPC 23 is formed with wiring 28 on a flexible substrate 27. The FPC 23 is provided with the electrodes 31 and 32 at positions to which the cathode takeout electrode 25 and the anode takeout electrode 26 of the OLED panel 20 are connected.

The wiring 28 of the FPC 23 is designed such that the respective OLED panels 20 are connected one another in series. Namely, the anode takeout electrode 26 of the OLED panel 20 is connected to the electrode 31 provided at a side of the wiring 28 serving as a transmission wiring from the electric power source portion. In addition, the cathode takeout electrode 25 of the OLED panel 20 is connected to the electrode 32 provided at a side of the wiring 28 serving as a return wiring to the electric power source portion. Furthermore, the cathode takeout electrode 25 and the anode takeout electrode 26 of each OLED panel 20 are connected to each other via the wiring 28, except for the cathode takeout electrode 25 of the OLED panel 20 provided closest to the return wiring side and the anode takeout electrode 26 of the OLED panel 20 arranged closest to the transmission wiring side. With this arrangement, the respective OLED panels 20 are connected to one another in series via the wiring 28.

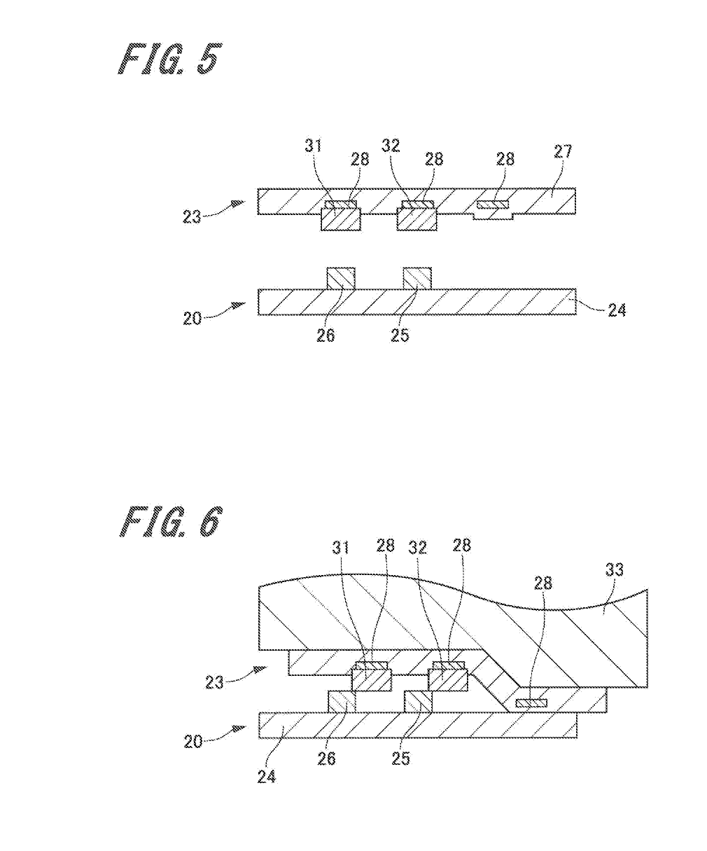

A method for joining the OLED panel 20 and the FPC 23 (mounting process) to each other will be described by the use of FIGS. 5 and 6. FIGS. 5 and 6 correspond to cross-sections along the line A-A of the icon display portion shown in FIG. 3.

First, as shown in FIG. 5, there are performed positional alignment between the electrodes 31 and 32 provided on the wiring 28, and those of the cathode takeout electrode 25 and the anode takeout electrode 26 of the OLED panel 20. At this time, an ACF (not shown) is provided between the OLED panel 20 and the FPC 23.

Then, as shown in FIG. 6, a crimping bar 33 of a thermal pressing tool is pressed from the FPC 23 side to thereby crimp the FPC 23 and the OLED panel 20. With this arrangement, the electrodes 31 and 32 of the FPC 23, and the cathode takeout electrode 25 and the anode takeout electrode 26 of the OLED panel 20 are electrically connected to each other via the ACF.

At this time, as shown in FIGS. 3 and 4, at a portion where the OLED panel 20 is joined, when the layout of the wiring 28 and the electrodes 31 and 32 of the FPC 23 are non-uniform, the pressure in the crimping becomes non-uniform. In addition, as FIG. 6, the OLED panel 20 and the FPC 23 cause positional misalignment.

Specifically, when there is a deviation in the layout of the wiring 28 and the electrodes 31 and 32 on a straight line that connects the electrodes 31 and 32 connected to one OLED panel 20, the crimping pressure is concentrated on one portion and thus the crimping pressure of the FPC 23 is deviated to one side. For example, as shown in FIG. 6, a position of the FPC 23 is deviated to the wiring 28 side by deviation of the pressure to the wiring 28 side. As a result, connection reliability between the electrodes 31 and 32 of the FPC 23 and the cathode takeout electrode 25 and the anode takeout electrode 26 of the OLED panel 20 is lowered.

Therefore, in the electronic device, there is generated a problem of the decrease in the mounting yield in the mounting process of the OLED panel.

In order to solve the problem described above, in the FPC 23 shown in FIG. 4, there is designed the layout of the portion where the OLED panel 20 is crimped such that the pressure in the crimping is not concentrated on one portion. Namely, the FPC 23 is laid out so as to have a pressure distribution in which FPC 23 does not cause the positional misalignment at the time of the crimping.

In the present invention, within a range in which the OLED panel is mounted, the layout of the FPC is designed such that the wiring and the electrodes become symmetrical with respect to the line corresponding to a direction perpendicular to a straight line that connects electrodes to be connected to the OLED panel. Namely, the FPC has the pattern that is symmetrical with respect to the line corresponding to the direction perpendicular to the straight line that connects the electrodes connected to the OLED panel.

The pattern of the electrodes and wiring formed on the FPC is formed to be symmetrical with respect to the line corresponding to the direction perpendicular to the straight line that connects the electrodes, and thus the deviation to one side of the crimping pressure is minimized. With this arrangement, when the OLED panel is crimped to the FPC, the pressure distribution can be adopted so as not to cause the positional misalignment between the FPC and the OLED panel.

Accordingly, the electronic device can minimize the decreases in the mounting yield of the OLED panel.

Hereinafter, specific embodiment of the electronic device of the present invention will be described, and in the descriptions below, the same configurations as those described in the summary of the electronic device will be omitted. Furthermore, the configurations shown in FIGS. 1 and 2 are common configurations in each embodiment described below. Therefore, in each embodiment, the FPC only has the different wiring and layout of the electrodes, and the OLED panel only has the different arrangement of the electrodes. Other configurations can be the same.

### 2. First Embodiment of Electronic Device

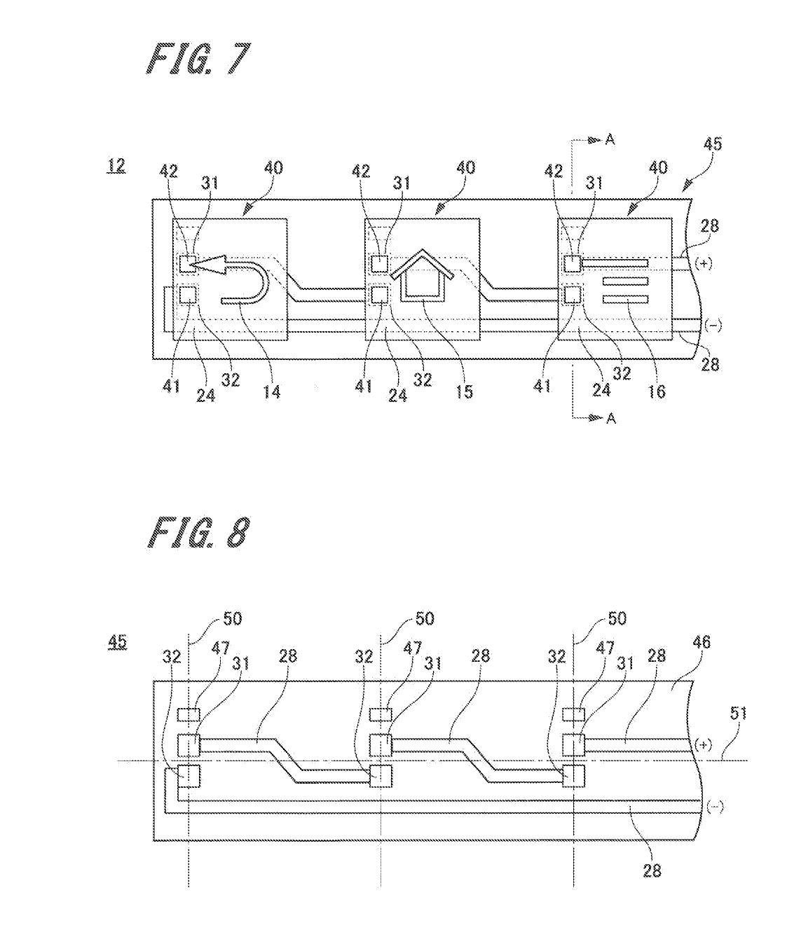

First embodiment of the electronic device will be described below. FIG. 7 shows an arrangement plan view of the OLED panel and the FPC at the icon display portion of the electronic device of the first embodiment.

As shown in FIG. 7, in this example, the three icons 14, 15, and 16 corresponding to each of the common function keys are provided at the icon display portion 12. The icons 14, 15, and 16 can be displayed by forming the light emitting layer in a predetermined pattern, on the individual OLED panel 40. The configurations are similar to those described above in the summary of the electronic device.

The OLED panel 40 is provided, on the substrate 24, with a cathode takeout electrode 41 and an anode takeout electrode 42 which are connected to the cathode electrode and the anode electrode described above to thereby be connected to the outside from the OLED panel 40. The cathode takeout electrode 41 and the anode takeout electrode 42 are connected to the electrodes 31 and 32 of an FPC 45 via the ACF (anisotropic conductive film) and the like (not shown).

FIG. 8 shows a layout of the FPC 45 to which the OLED panel 40 is connected. The FPC 45 is formed with the wiring 28 on a flexible substrate 46. In addition, the FPC 45 is provided with the electrodes 31 and 32 at positions to which the cathode takeout electrode 41 and the anode takeout electrode 42 of the OLED panel 40 are connected. Furthermore, the FPC 45 is provided with a dummy electrode 47.

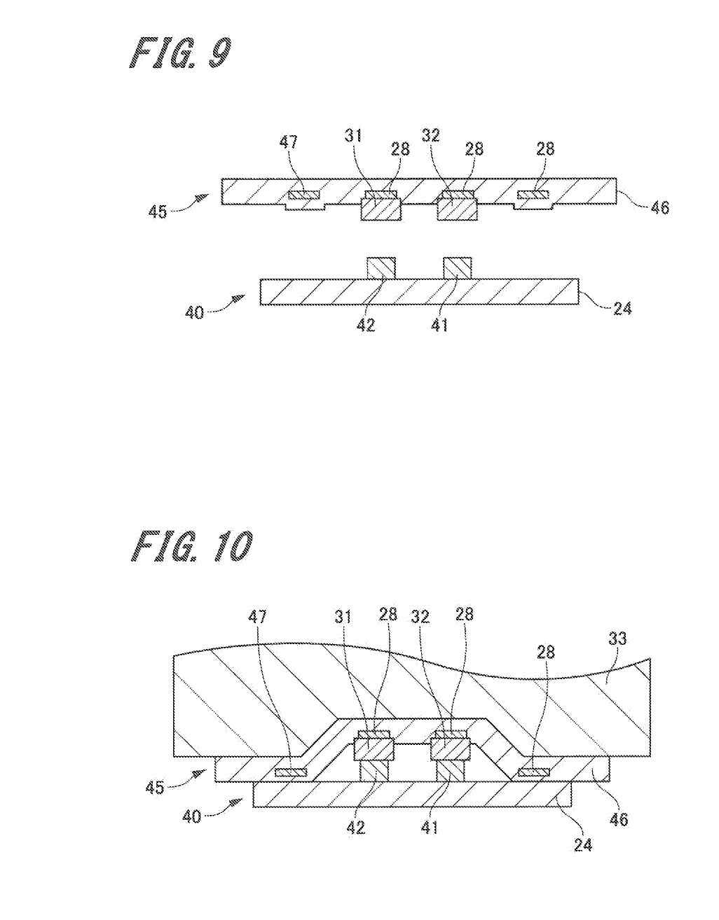

FIGS. 9 and 10 show cross-sectional views of the icon display portion. FIGS. 9 and 10 correspond to the cross-section along the line A-A of the icon display portion shown in FIG. 7. FIG. 9 shows a state where positions of the FPC 45 and the OLED panel 40 are aligned before being joined to each other. Furthermore, FIG. 10 shows a state where the FPC 45 and the OLED panel 40 are pressed from a FPC 45 side with the crimping bar 33 of the thermal pressing tool and thus are crimped to each other.

As shown in FIGS. 9 and 10, the connection between the FPC 45 and the OLED panel 40 is carried out, respectively, by the electrodes 31 and 32 protruding from the flexible substrate 46, and the cathode takeout electrode 41 and the anode takeout electrode 42 protruding from the substrate 24. Accordingly, in a direction in which the respective electrodes to be connected are aligned, when the crimping pressure is deviated in one direction, there is caused the positional misalignment in the mounting as shown in FIG. 6 described above. Therefore, in order to prevent the positional misalignment between the FPC 45 and the OLED panel 40, it is sufficient that there is adopted the pressure distribution so as not to cause the positional misalignment, in the direction in which the respective electrodes to be connected are aligned.

Therefore, as shown in FIG. 10, when the FPC 45 is heated to be crimped to the OLED panel 40, in order that the crimping pressure may be distributed so as not to cause the positional misalignment, there may be adopted a layout in which a portion of the FPC 45 where the OLED panel 40 is arranged has less deviation of the pattern, in the direction in which the respective electrodes to be connected are aligned. Namely, in a direction in which the electrodes 31 and 32 to be connected to one OLED panel 40 and to be paired are aligned, each pattern of the FPC 45 may be arranged in a symmetrical manner. A range in which the symmetrical property of the pattern is required on the FPC 45 may be within a range in which the crimping pressure is applied, and thus the range may be within a range in which the OLED panel 40 is arranged as described above.

FIG. 8 shows a layout of the FPC 45 in which the each pattern of the FPC 45 is symmetrical, in the direction in which the electrodes 31 and 32 to be connected to one OLED panel 40 and to be paired are aligned as described above. In the layout of the FPC 45 shown in FIG. 8, a line passing a center of the electrode 31 and a center of the electrode 32 is defined as a straight line 50. In addition, in a direction perpendicular to the straight line 50, there is positioned a symmetrical axis 51 with respect to which the each pattern of the FPC 45 becomes symmetrical. Namely each pattern of the FPC 45 is laid out such that the each pattern is symmetrical with respect to the symmetrical axis 51.

In the layout of the FPC 45 shown in FIG. 8, the symmetrical axis 51 is positioned between the electrode 31 and the electrode 32. In addition, the electrode 31 and the electrode 32 are arranged at positions where they are symmetrical to each other with respect to the symmetrical axis 51. Furthermore, the dummy electrode 47 is provided at a position to be symmetrical to the wiring 28 with respect to the symmetrical axis 51.

With the layout as described above, the pattern of the FPC 45 within the range where the OLED panel 40 is arranged is set to be symmetrical with respect to the symmetrical axis 51 in the direction in which the electrodes 31 and 32 to be connected to the one OLED panel 40 and to be paired are aligned.

Furthermore, as shown in FIG. 7, the cathode takeout electrode 41 and the anode takeout electrode 42 of the OLED panel 40 are also provided at positions in accordance with the symmetrical property of the FPC 45. Namely, the OLED panel 40 is arranged at a position where the cathode takeout electrode 41 and the anode takeout electrode 42 of the OLED panel 40 are symmetrical to each other with respect to the symmetrical axis 51. Moreover, on the OLED panel 40, at a position on the FPC 45 to which the OLED panel 40 is connected, the cathode takeout electrode 41 and the anode takeout electrode 42 are provided at the position where the cathode takeout electrode 41 and the anode takeout electrode 42 are symmetrical to each other with respect to the above described symmetrical axis 51.

With the layout described above, in the direction in which the respective electrodes to be connected are aligned, the pattern of the FPC 45 has less deviation at a portion where the OLED panel 40 is arranged. Accordingly, as shown in FIG. 10, the pressure at the time of the crimping is uniformly distributed centering around the symmetrical axis 51 on both sides in a direction of the straight line 50. Therefore, when the crimping bar 33 of the thermal pressing tool is used for heating and crimping, crimping distribution can be adopted so as not to cause the positional misalignment between the OLED panel 40 and the FPC 45.

As described above, if the pattern of the FPC 45 is arranged to be symmetrical with respect to the symmetrical axis 51 as described above at a connecting position of the OLED panel 40, the positional misalignment due to the deviation of the pressure distribution can be suppressed. Accordingly, in the production of the electronic devices, it is possible to minimize the decrease in the mounting yield in the mounting process of the OLED panel.

In order to enhance the symmetrical property of the layout of the FPC 45, it is preferable that the electrode 31 and the electrode 32 be formed in the same shape. In addition, a width of the wiring 28 on the straight line 50 and a length (width) of the dummy electrode 47 in a direction of the straight line 50 are preferably the same.

This example describes a case where the dummy electrode 47 is not connected to the wiring 28 and has an island-like shape independent for each portion where the OLED panel 40 is arranged, but other configuration may be adopted. For example, there can also be adopted a continuous dummy wiring pattern under a plurality of OLED panels 40 to be arranged. Furthermore, a length and a size of the dummy wiring can be arbitrarily changed.

Connection between the FPC 45 and the OLED panel 40 is connection between protruding electrodes, and thus a pattern shape in the direction in which the protruding electrodes are aligned (direction of the straight line 50) exerts a large influence on the pressure distribution when the crimping is performed, but exerts a small influence on the pressure distribution of other patterns. Accordingly, the length of the dummy electrode 47 in the direction of the symmetrical axis 51 is preferably larger than the length of the electrodes 31 and 32 in the direction of the symmetrical axis 51.

Furthermore, in the OLED panel 40, the cathode takeout electrode 41 and the anode takeout electrode 42 of the substrate 24 are preferably formed so as to be symmetrical to each other with respect to the symmetrical axis 51. Namely, it is preferable that the symmetrical axis 51 is positioned at a center between the cathode takeout electrode 41 and the anode takeout electrode 42, and a center of the OLED panel 40 in the direction of the straight line 50 described above corresponds to the symmetrical axis 51.

As shown in FIGS. 7 and 8, when the symmetrical axis 51 is positioned at the center of the OLED panel 40 in the direction of the straight line 50, as shown in FIG. 10, joining areas between the FPC 45 and the OLED panel 40 are the same on both sides of the symmetrical axis 51 in the direction of the straight line 50. Accordingly, the deviation of the pressure distribution at the time of the crimping becomes further smaller, and the positional misalignment when the FPC 45 and the OLED panel 40 are joined to each other can be further suppressed.

### 3. Second Embodiment of Electronic Device

Hereinafter, the second embodiment of the electronic device will be described. FIG. 11 shows an arrangement plan view of the OLED panel and the FPC at the icon display portion of the electronic device of the second embodiment.

As shown in FIG. 11, the three icons 14, 15, and 16 corresponding to the common function keys are included in the icon display portion 12. The icons 14, 15, and 16 are formed such that they can be displayed by forming the light emitting layer in the predetermined pattern on an individual OLED panel 60. These configurations are similar to the configurations described in the summary of the electronic device.

The OLED panel 60 is provided, on the substrate 24, with a cathode takeout electrode 61 and an anode takeout electrode 62 which are connected to the cathode electrode and the anode electrode described above to be connected to the outside from the OLED panel 60. The cathode takeout electrode 61 and the anode takeout electrode 62 are connected to electrodes 72 and 73 of the FPC 70 via the ACF (anisotropic conductive film) and the like (not shown).

Furthermore, the OLED panel 60 is provided with a dummy electrode 63. In addition, the dummy electrode 63 of the OLED panel 60 is connected to a dummy electrode 74 provided on the FPC 70 via the ACF (not shown).

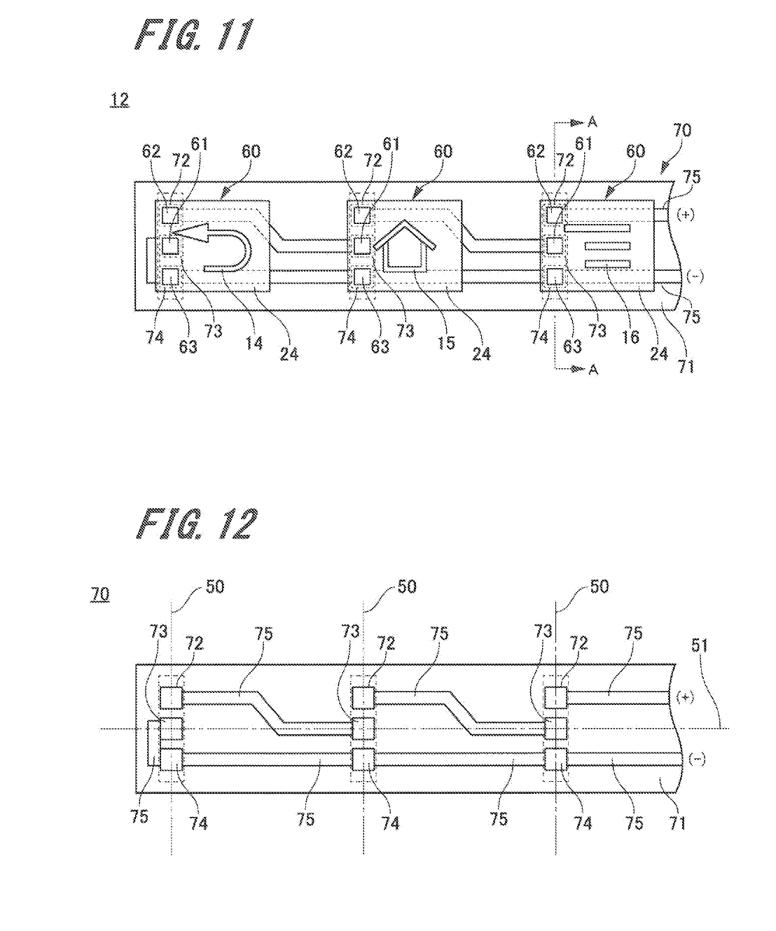

FIG. 12 shows a layout of the FPC 70 to which the OLED panel 60 is connected. The FPC 70 is a flexible substrate formed with a wiring 75 on a flexible substrate. Furthermore, the FPC 70 is provided with the electrodes 72 and 73 at positions to which the cathode takeout electrode 61 and the anode takeout electrode 62 of the OLED panel 60 are connected.

Furthermore, the FPC 70 is provided with the dummy electrode 74. The dummy electrode 74 is provided at a position where it is connected to the wiring 75 serving as a return wiring along a direction in which the electrodes 72 and 73 to be connected to one OLED panel 60 and to be paired are aligned. Moreover, the dummy electrode 63 is provided on the OLED panel 60 in accordance with a position of the dummy electrode 74 of the FPC 70. As shown in FIG. 11, the dummy electrode 74 of the FPC 70 and the dummy electrode 63 of the OLED panel 60 are connected to each other.

Therefore, as shown in FIG. 12, in the FPC 70, the electrodes 72 and 73 of the FPC 70 to be connected to one OLED panel 60, and the dummy electrode 74 of the FPC 70 are arranged so as to be aligned in one line.

Furthermore, in alignment with the electrodes 72 and 73 and the dummy electrode 74 of the FPC 70, the cathode takeout electrode 61, the anode takeout electrode 62, and the dummy electrode 63 are arranged so as to be aligned in one line, also on the OLED panel 60.

Also in the second embodiment, in a similar way to the above-described first embodiment, when the FPC 70 and the OLED panel 60 are heated to be crimped to each other, it is necessary to distribute the crimping pressure so as not to cause the positional misalignment. Therefore, in a direction in which the electrodes 72 and 73 of the FPC 70 to be connected to the OLED panel 60 are aligned, the FPC 70 at a portion where the OLED panel 60 is arranged is required to have a layout with less deviation of pattern.

In the layout of the FPC 70 shown in FIG. 12, a line passing a center of the electrode 72 and a center of the electrode 73 to be connected to the one OLED panel 40 and to be paired is defined as the straight line 50. In a direction perpendicular to the straight line 50, there is positioned the symmetrical axis 51 with respect to which each pattern of the FPC 70 becomes symmetrical. Namely, the layout of each pattern of the FPC 70 is set such that each pattern is symmetrical with respect to the symmetrical axis 51.

In the layout of the FPC 70 shown in FIG. 12, the symmetrical axis 51 is positioned at the center of the electrode 73, and the electrode 73 is formed in a shape of being symmetrical with respect to the symmetrical axis 51. Furthermore, the dummy electrode 74 is provided at a position that is symmetrical to the electrode 72 with respect to the symmetrical axis 51. With the layout described above, the pattern of the FPC 70 within a range in which the OLED panel is arranged becomes symmetrical with respect to the symmetrical axis 51, in the direction in which the electrodes 72 and 73 that are to be connected to the one OLED panel 60 and to be paired are aligned.

Furthermore, as shown in FIG. 11, the cathode takeout electrode 61, the anode takeout electrode 62 and the dummy electrode 63 of the OLED panel 60 are also provided at positions in accordance with the symmetrical property of the FPC 70. On the OLED panel 60, the symmetrical axis 51 is positioned at a center of the cathode takeout electrode 61, and the dummy electrode 63 is provided at a position that becomes symmetrical to the anode takeout electrode 62 with respect to the symmetrical axis 51. The dummy electrode 63 of the OLED panel 60 is formed as an independent pattern that is not connected to a configuration of an electrode or the like of an organic EL element formed on the OLED panel 60.

The dummy electrode 74 is formed on the wiring 75 serving as the return wiring, and thus the flexible substrate 71 does not need to newly include a region where the dummy electrode 74 is formed, thereby allowing the reduction in size of the FPC 70. Furthermore, the FPC 70 efficiently utilizes the wiring 75 that is an essential configuration, and thus extra pattern such as the dummy wiring is not required be newly formed, thereby resulting in being advantageous for the reduction in size.

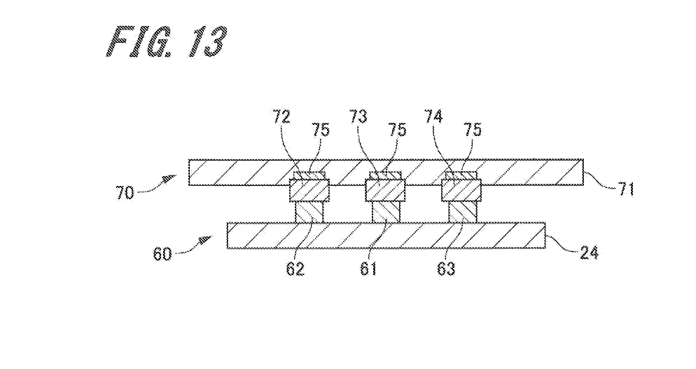

The layout is set such that the FPC 70 becomes symmetrical with respect to the symmetrical axis 51 as described above, and thus, when the FPC 70 and the OLED panel 60 are joined to each other, as shown in FIG. 13, the pressure at the time of the crimping is uniformly distributed centering around the symmetrical axis 51 on both sides in the direction of the straight line 50. Therefore, if the pattern of the FPC 70 is symmetrically arranged at the position where the OLED panel 60 is connected, the positional misalignment caused by the deviation of the pressure distribution can be suppressed.

Note that, in the embodiment described above, shapes of the respective electrodes formed on the FPC and those thereof formed on the OLED panel can be arbitrary. In order to enhance the symmetrical property, the shapes of the electrodes provided at the symmetrical positions are preferably the same. Furthermore, even when the shapes of the electrodes provided at the symmetrical positions are different, it is sufficient that the deviation of the pressure distribution may not be generated at the time of the crimping. Accordingly, it is sufficient that the symmetrical pattern with respect to the symmetrical axis is arranged such that the symmetrical patterns are at least partially overwrapped with each other when the pattern is folded with respect to the symmetrical axis. The pattern to be symmetrical includes the pattern of the arrangement described above. For example, it is sufficient that the pair of electrodes (dummy electrodes) that are symmetrical with respect to the symmetrical axis may be arranged so as to be at least partially overlapped with the electrodes (dummy electrode) at a position being symmetrical when the pattern is folded back with respect to the symmetrical axis. Furthermore, similarly in the dummy wiring pattern, the dummy wiring may be formed at the position where the dummy wiring is at least partially overlapped with a wiring at the position being symmetrical with respect to, at least, the symmetrical axis.

Moreover, as long as the FPC has a layout that is symmetrical with respect to the symmetrical axis, the FPC may also have patterns for wirings, electrodes and others, regardless of types of patterns. The pattern of the FPC may be laid out so as to be symmetrical with respect to the symmetrical axis, by combination of the patterns described above. For example, in the first embodiment, the layout may be set such that the transmission wiring is arranged instead of the dummy wiring, and the wirings of the transmission wiring and the return wiring become symmetrical with respect to the symmetrical axis. Furthermore, as long as the symmetrical property is not deteriorated, other wiring pattern may be formed instead of the dummy wiring.

Note that the present invention is not limited to the configurations described in the above embodiments, and additional various modifications and changes are possible within the scope not departing from the configuration of the present invention.

### REFERENCE SIGNS LIST

10 smart device

11 main display screen

12 icon display portion

13 common function key

14 icon

17 cover glass

18 casing

19 main display panel

20, 40, 60 OLED panel

21 PCB

22, 23, 45, 70 FPC

24 substrate

25, 41, 61 cathode takeout electrode

26, 42, 62 anode takeout electrode

27, 46, 71 flexible substrate

31, 32, 72, 73, 28, 75 electrode

33 crimping bar

50 straight line

51 symmetrical axis

63, 74, 47 dummy electrode

1. An electronic device in which an OLED (organic light emitting diode) panel and an FPC (flexible printed circuit) are crimped and connected to each other using an ACF (anisotropic conductive film), wherein the FPC has a pattern that is symmetrical with respect to a line corresponding to a direction perpendicular to a straight line that connects electrodes connected to the OLED panel with each other within a range in which the OLED panel is mounted.

2. The electronic device according to claim 1, wherein the FPC has a pattern that is symmetrical on an extended line of the straight line that connects the electrodes connected to the OLED panel with each other.

3. The electronic device according to claim 1, wherein a symmetrical axis with respect to which the pattern is symmetrical is located between the electrodes of the FPC.

4. The electronic device according to claim 1, having a dummy wiring pattern on the extended line of the straight line that connects the electrodes connected to the OLED panel with each other.

5. The electronic device according to claim 1, comprising a dummy electrode on the extended line of the straight line that connects the electrodes connected to the OLED panel with each other.

6. The electronic device according to claim 5, wherein the dummy electrode is connected to a return wiring.
